(19) United States
(12) Patent Application Publication
(10) Pub. No.: US 2020/0075554 A1
(43) Pub. Date: Mar. 5, 2020

(54) ELECTRONIC PACKAGE AND METHOD FOR FABRICATING THE SAME

(71) Applicant: PHOENIX & CORPORATION, Grand Cayman (KY)

(72) Inventors: Che-Wei Hsu, Hsinchu County (TW); Chu-Chin Hu, Hsinchu County (TW); Shih-Ping Hsu, Hsinchu County (TW)

(21) Appl. No.: 16/558,443

(22) Filed: Sep. 3, 2019

(30) Foreign Application Priority Data
Sep. 5, 2018 (TW) 107131134

(51) Int. Cl. H01L 25/065; H01L 23/532; H01L 23/528; H01L 23/522; H01L 23/00; H01L 23/31; H01L 21/56

(52) U.S. Cl. CPC H01L 25/0657; H01L 23/53228; H01L 23/5283; H01L 23/5226; H01L 24/09; H01L 2924/381; H01L 24/32; H01L 24/73; H01L 23/3128; H01L 21/563; H01L 24/17

(57) ABSTRACT

An electronic package includes a circuit structure having a first electronic component disposed on one side thereof, and a second electronic component and conductive pillars disposed on the other side thereof. The second electronic component and the conductive pillars are encapsulated by an encapsulant, and end faces of the conductive pillars are exposed from the encapsulant, allowing the exposed end faces to be connected to an external circuit board. As the end faces of the conductive pillars are used as contact structures, fine-pitch electronic packages can be achieved. Also, by providing sufficient space attributed to the tall columnar structures of the conductive pillars, the second electronic component of an appropriate thickness can be obtained, allowing the electronic package to be suitable for applications requiring high voltages and/or high currents. A method for fabricating an electronic package is further provided.

### BACKGROUND

### 1. Technical Field

The present disclosure relates to semiconductor packages, and, more particularly, to a multi-chip electronic package and a method for fabricating the same.

### 2. Description of Related Art

Electronic products having multiple functionalities and high performance are becoming more and more popular in the thriving electronic industry. In order to satisfy the need for miniaturization of electronic packages, chip scale packaging (CSP) technique has been developed.

FIGS. 1A to 1E are cross-sectional diagrams illustrating a method for fabricating a semiconductor package 1 according to the prior art.

As shown in FIG. 1A, a release layer 100 is formed on a carrier 10. A plurality of semiconductor chips 11 are then provided on the release layer 100. Each of the semiconductor chips 11 has an active face 11a and a non-active face 11b opposing the active face 11a. A plurality of electrode pads 110 are provided on the active faces 11a, which are adhered onto the release layer 100.

As shown in FIG. 1B, an encapsulant 14 is formed on the release layer 100 and encapsulates the semiconductor chips 11.

As shown in FIG. 1C, the release layer 100 and the carrier 10 are removed to expose the active faces 11a of the semiconductor chips 11.

As shown in FIG. 1D, a circuit structure 16 is disposed on the encapsulant 14 and the active faces 11a of the semiconductor chips 11, and electrically connected with the electrode pads 110. Then, an insulating protective layer 18 is formed on the circuit structure 16, and a portion of the surface of the circuit structure 16 is exposed from the insulating protective layer 18 for solder bumps 17 to be bonded thereto.

As shown in FIG. 1E, a singulation process is performed along cutting paths L shown in FIG. 1D, thereby obtaining a plurality of semiconductor packages 1. The solder bumps 17 on the semiconductor package 1 are then reflowed for a circuit board (not shown) to be electrically connected therewith.

However, in order to meet the demand for miniaturization, the line pitches of the circuit structure 16 of the semiconductor package 1 are becoming smaller, resulting in smaller pitches between the solder bumps 17. This may easily lead to bridging, and thus short circuits, between the adjacent solder bumps 17 after reflow of the solder bumps 17, which give rise to lowered production yield and poor reliability.

Furthermore, in the semiconductor package 1, in order to meet the needs for multiple functionalities and high performance in the end products, a plurality of semiconductor chips 11 are formed on the same plane (as shown in FIG. 1E) in the singulation process. This leads to a large planar area of the overall structure of a semiconductor package 1 and makes it difficult to reduce the volume of the end product.

In addition, in order to satisfy the need for semiconductor packages 1 of smaller thickness, the semiconductor chips 11 are often thinned. However, the structural strengths of the thinned semiconductor chips 11 are often insufficient and may lead to cracking of the semiconductor chips 11. Moreover, the layout space for integrated circuits of the thinned semiconductor chips 11 is more limited, and as a result, the semiconductor chips 11 are not suited for applications which require high voltages and/or high currents.

Therefore, there is a need for a solution that reduces the volumes of the traditional multi-chip semiconductor packages.

### SUMMARY

In view of the aforementioned shortcomings of the prior art, an electronic package is provided by the present disclosure. The electronic package may include a circuit structure including a first side and a second side opposing the first side; a first electronic component disposed on the first side of the circuit structure; a first encapsulant encapsulating the first electronic component; a second electronic component disposed on the second side of the circuit structure; a plurality of conductive pillars disposed on the second side of the circuit structure and electrically connected with the circuit structure; and a second encapsulant encapsulating the second electronic component and the conductive pillars and including a first surface bonded to the circuit structure and a second surface opposing the first surface, wherein end faces of the conductive pillars are exposed from the second surface of the second encapsulant.

A method for fabricating an electronic package is also provided, which may include: providing a package assembly including a circuit structure having a first side and a second side opposing the first side, a first electronic component disposed on a first side of the circuit structure, and a first encapsulant encapsulating the first electronic component; providing a second electronic component on a second side of the circuit structure; forming a plurality of conductive pillars on the second side of the circuit structure and electrically connecting the conductive pillars with the circuit structure; forming on the second side of the circuit structure a second encapsulant that encapsulates the second electronic component and the conductive pillars, wherein the second encapsulant includes a first surface bonded to the circuit structure and a second surface opposing the first surface; and removing a portion of the second encapsulant to expose end faces of the conductive pillars from the second surface of the second encapsulant.

In an embodiment, the circuit structure includes a plurality of conductive blind vias electrically connected with the first electronic component.

In an embodiment, the first electronic component includes an active face electrically connected with the circuit structure and a non-active face opposing the active face. In another embodiment, the non-active face of the first electronic component is exposed from the first encapsulant.

In an embodiment, the second electronic component includes an active face electrically connected with the circuit structure and a non-active face opposing the active face. In an embodiment, the second electronic component is electrically connected with the circuit structure in a flip-chip manner. In yet another embodiment, the non-active face of the second electronic component is exposed from the second surface of the second encapsulant.

In an embodiment, the conductive pillars are copper pillars.

In an embodiment, a conductive adhesive layer is formed between the conductive pillars and the second side of the circuit structure.

In an embodiment, conductive components are disposed on the end faces of the conductive pillars.

Therefore, the electronic package and the method for fabricating an electronic package in accordance with the present disclosure exploit the conductive pillars as contact structures. Therefore, compared with the prior art, the electronic package according to the present disclosure is suitable for packages requiring a fine pitch as the conductive pillars occupy smaller areas than solder balls, and bridging of the soldering materials can thus be prevented. Also, by providing sufficient space through the tall columnar structures of these conductive pillars, the appropriate thickness of the electronic component can be achieved in order to maintain the structural strength, allowing it to be appropriate for applications that require high voltages and/or high currents. Product yield is also enhanced.

Moreover, the first electronic component and the second electronic component are provided on the first side and the second side of the circuit structure, respectively, thereby providing a stacked configuration. Thus, compared with the multi-chip planar configuration of the semiconductor package according to the prior art, the planar area of the electronic package according to the present disclosure is significantly reduced, thereby meeting the demands for multiple functionalities and high performance.

### BRIEF DESCRIPTION OF THE DRAWINGS

FIGS. 1A to 1E are cross-sectional diagrams illustrating a method for fabricating semiconductor packages in the prior art.

FIGS. 2A to 2D are cross-sectional diagrams illustrating a method for fabricating an electronic package in accordance with the present disclosure.

FIGS. 2C′ and 2C″ are cross-sectional diagrams illustrating alternative embodiments of FIG. 2C.

FIGS. 2D′ and 2D″ are cross-sectional diagrams illustrating alternative embodiments of FIG. 2D.

### DETAILED DESCRIPTION OF THE EMBODIMENTS

Aspects of the present disclosure are described by the following specific embodiments. The advantages and effects of the present disclosure can be readily understood by one of ordinary skill in the art upon reading the disclosure of this specification.

It should be noted that the structures, ratios, sizes shown in the drawings appended to this specification are to be construed in conjunction with the disclosure of this specification in order to facilitate understanding of those skilled in the art. They are not meant, in any ways, to limit the implementations of the present disclosure, and therefore have no substantial technical meaning. Without affecting the effects created and objectives achieved by the present disclosure, any modifications, changes or adjustments to the structures, ratio relationships or sizes, are to be construed as fall within the range covered by the technical contents disclosed herein. Meanwhile, terms, such as “above”, “first”, “second”, “one”, “a”, “an”, and the like, are for illustrative purposes only, and are not meant to limit the range implementable by the present disclosure. Any changes or adjustments made to their relative relationships, without modifying the substantial technical contents, are also to be construed as within the range implementable by the present disclosure.

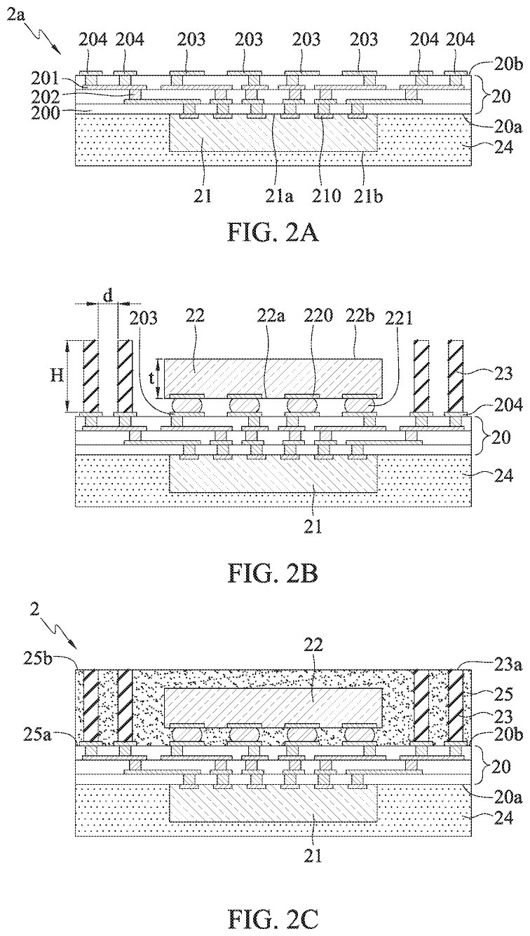

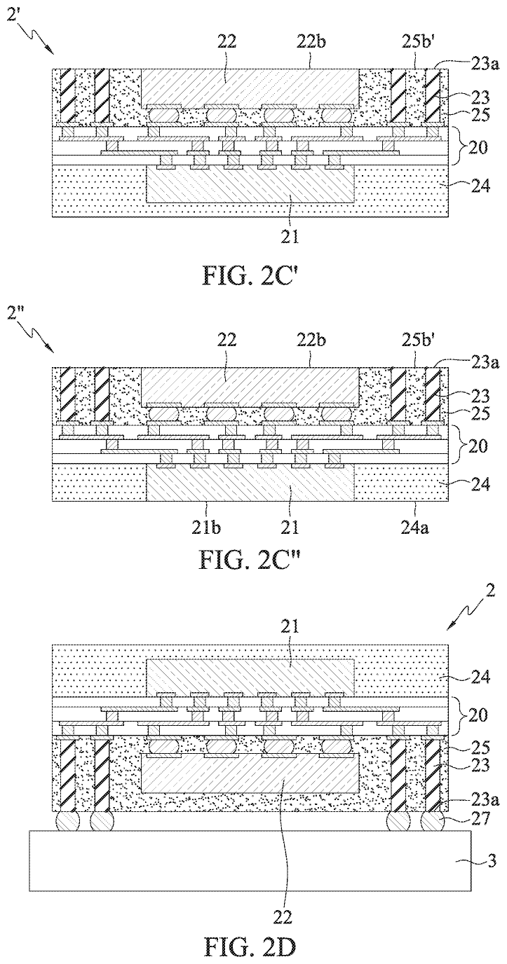

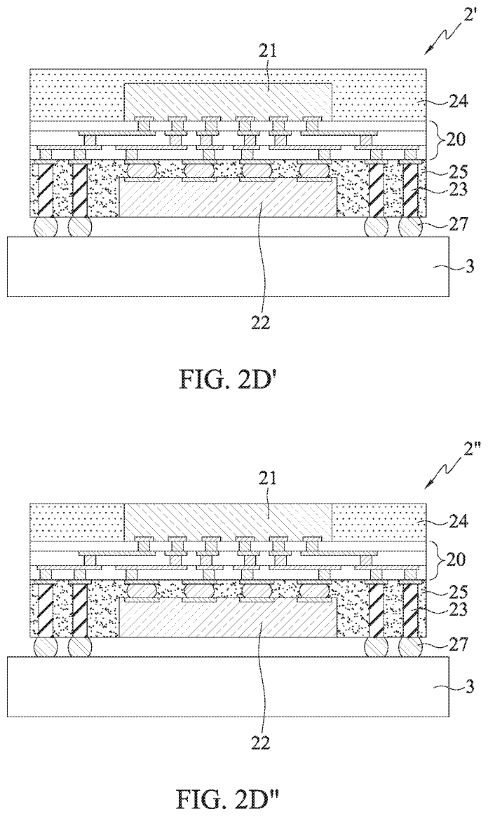

FIGS. 2A to 2E are cross-sectional diagrams illustrating a method for fabricating a semiconductor package 2 in accordance with the present disclosure.

As shown in FIG. 2A, a package assembly 2a is provided, including a circuit structure 20, at least one first electronic component 21 and a first encapsulant 24.

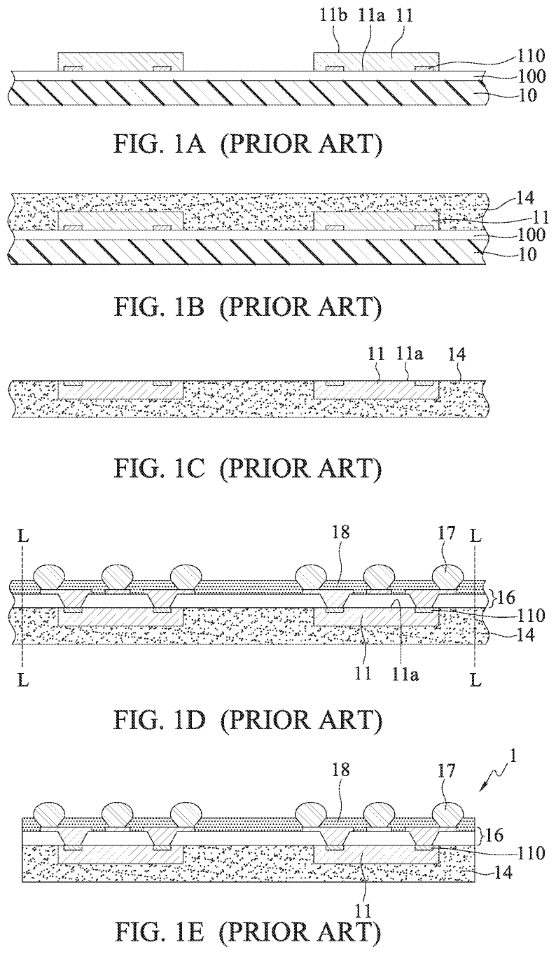

In an embodiment, one may refer to the fabrication method already described with reference to FIGS. 1A to 1E for the method for fabricating the package assembly 2a, but the present disclosure is not limited as such.

The circuit structure 20 includes a first side 20a and a second side 20b opposing the first side 20a. In an embodiment, the circuit structure 20 includes at least one insulating layer 200, a circuit layer 201 disposed on the insulating layer 200, and a plurality of conductive blind vias 202 provided in the insulating layer 200 and electrically connected with the circuit layer 201. In an embodiment, the circuit layer 201 is formed of gold, silver, copper or other similar types of conductive materials. In another embodiment, the insulating layer 200 is formed of a dielectric material, such as polybenzoxazole (PBO), polyimide (PI) or a prepreg.

In an embodiment, a portion of the circuit layer 201 on the second side 20b of the circuit structure 20 is defined as first electrical contact pads 203 and second electrical contact pads 204.

The first electronic component 21 is bonded to the first side 20a of the circuit structure 20. The first electronic component 21 can be an active element, a passive element or a combination of both. In an embodiment, the active element is a semiconductor chip; the passive element is a resistor, a capacitor or an inductor. In an embodiment, the first electronic component 21 is a semiconductor chip having an active face 21a and a non-active face 21b opposing the active face 21a. The active face 21a includes a plurality of electrode pads 210 for electrically connecting with the conductive blind vias 202. In an embodiment, the first electronic component 21 is electrically connected with the circuit layer 201 via its active face 21a in a flip-chip manner. In another embodiment, the first electronic component 21 is electrically connected with the circuit layer 201 via a plurality of solder wires (not shown) by the wire bonding method. However, the manner in which the first electronic component 21 is electrically connected with the circuit structure 20 is not limited to those mentioned above.

The first encapsulant 24 is formed on the first side 20a of the circuit structure 20 by molding, coating, lamination, or the like. The first encapsulant 24 is made of a dielectric material, such as epoxy resin. The epoxy resin may further include a molding compound or a primer, e.g., an epoxy molding compound (EMC), wherein the EMC includes fillers of 70 to 90 wt %.

As shown in FIG. 2B, a second electronic component 22 is disposed on the first electrical contact pads 203 of the circuit structure 20, and a plurality of conductive pillars 23 are disposed on the second side 20b of the circuit structure 20.

In an embodiment, the second electronic component 22 is an active element, a passive element or a combination of both. In another embodiment, the active element is a semiconductor chip. In yet another embodiment, the passive element is a resistor, a capacitor or an inductor. In an embodiment, the second electronic component 22 is a semiconductor chip having an active face 22a and a non-active face 22b opposite to the active face 22a. A plurality of electrode pads 220 are disposed on the active face 22a, and a plurality of conductive bumps 221 are bonded onto the electrode pads 220 for the first electrical contact pads 203 to be electrically connected with in the flip-chip manner. In an embodiment, the conductive bumps 221 are metal materials, such as solder balls, copper pillars, solder bumps, and the present disclosure is not limited to these. In another embodiment, the second electronic component 22 is electrically connected with the first electrical contact pads 203 via a plurality of solder wires (not shown) by the wire bonding method. In yet another embodiment, the second electronic component 22 is in direct contact with the first electrical contact pads 203. However, the manner in which the second electronic component 22 is electrically connected with the first electrical contact pads 203 is not limited to those mentioned above.

In an embodiment, the conductive pillars 23 are copper pillars or other types of metal pillars, which are bonded to and in electrically connection with the second electrical contact pads 204. In an embodiment, the conductive pillars 23 have a height h greater than 200 μm, a distance d between two neighboring ones of the conductive pillars 23 is less than 300 μm, and the thickness t of the second electronic component 22 can be adjusted (e.g., increased) on demands.

In an embodiment, the conductive pillars 23 are in the shape of round columns, rectangular columns or any arbitrarily-shaped columns, depending on the shape of the second electrical contact pads 204 or other design needs, and the present disclosure is not limited as such.

In an embodiment, the conductive pillars 23 are directly disposed on the second electrical contact pads 204 through electroplating or other deposition methods. In another embodiment, the conductive pillars 23 are pre-disposed and bonded onto the first encapsulant 24 via a conductive adhesive layer, such as a conductive silver or copper paste (not shown). Nonetheless, there is no specification limitation on how the conductive pillars 23 are manufactured.

As shown in FIG. 2C, a second encapsulant 25 is formed on the second side 20b of the circuit structure 20, and encapsulates the second electronic component 22 and the conductive pillars 23. In an embodiment, the second encapsulant 25 includes a first surface 25a bonded to the circuit structure 20 and a second surface 25b opposite to the first surface 25a. Then, the second encapsulant 25 is partially removed, such that end faces 23a of these conductive pillars 23 are exposed from the second surface 25b of the second encapsulant 25.

In an embodiment, the second encapsulant 25 is made of a dielectric material, such as epoxy resin. In another embodiment, the epoxy resin further includes a molding compound or a primer, e.g., an epoxy molding compound (EMC). In yet another embodiment, the EMC includes fillers of 70 to 90 wt %.

In an embodiment, the first encapsulant 24 and the second encapsulant 25 can be made of the same material or different materials.

In an embodiment, through a planarization process, the end faces 23a of the conductive pillars 23 are exposed from the second surface 25b of the second encapsulant 25. In another embodiment, the planarization process includes polishing to remove portions of the second encapsulant 25, as well as portions of the conductive pillars 23 as needed. In yet another embodiment, both the non-active face 22b of the second electronic component 22 and the end faces 23a of the conductive pillars 23 can be exposed from the second surface 25b′ of the second encapsulant 25 as shown in FIG. 2C′.

In another embodiment, the non-active face 21b of the first electronic component 21 is also exposed from the first encapsulant 24 through a planarization process (e.g., a polishing process) as shown in FIG. 2C″.

As shown in FIG. 2D, following the manufacturing step shown in FIG. 2C, a plurality of conductive components 27 (e.g., solder balls) are disposed on the exposed end faces 23a of the conductive pillars 23 for an electronic device 3, such as a package structure, a circuit board or a chip, to be connected thereto subsequently. Similarly, following the manufacturing step shown in FIG. 2C′ or 2C″, a plurality of conductive components 27 may also be formed on the exposed end faces 23a of the conductive pillars 23 for an electronic device 3 to be connected thereto subsequently, as shown in FIGS. 2D′ or 2D″.

Therefore, the method for fabricating an electronic package 2, 2′, 2″ in accordance with the present disclosure allows the end faces 23a of the conductive pillars 23 exposed from the second surface 25b, 25b′ of the second encapsulant 25 to be used as contact structures. Compared to the prior art, the present disclosure employs the conductive pillars 23 to occupy smaller areas than solder balls, which makes the electronic package 2 according to the present disclosure more suitable to packages requiring fine pitch as bridging of the soldering materials can be prevented. Also, by providing sufficient space through the tall columnar structures of the conductive pillars 23, the present disclosure can achieve the appropriate thickness of the second electronic component 22 in order to maintain the structural strength and increase layout area for the integrated circuits, making it ideal for applications requiring high voltages and/or high currents. Product yield is also enhanced.

Moreover, the first electronic component 21 and the second electronic component 22 are provided on the first side 20a and the second side 20b of the circuit structure 20, respectively, thereby providing a stacked configuration. Thus, compared to the multi-chip planar configuration of the traditional semiconductor package, the planar area of the electronic package 2 is significantly reduced by the fabrication method of the present disclosure, thereby meeting the demands for multiple functionalities and high performance.

An electronic package 2, 2′, 2″ is also provided by the present disclosure (with reference to FIGS. 2D, 2D′, 2D″, respectively), which includes: a circuit structure 20, at least one first electronic component 21, a first encapsulant 24, at least one second electronic component 22, a second encapsulant 25, and a plurality of conductive pillars 23.

The circuit structure 20 includes a first side 20a and a second side 20b opposite to the first side 20a.

The first electronic component 21 is bonded to the first side 20a of the circuit structure 20.

The first encapsulant 24 is formed on the first side 20a of the circuit structure 20, and encapsulates the first electronic component 21.

The second electronic component 22 is provided on the second side 20b of the circuit structure 20.

The conductive pillars 23 are disposed on the second side 20b of the circuit structure 20 and electrically connected with the circuit structure 20.

The second encapsulant 25 is formed on the second side 20b of the circuit structure 20 and encapsulates the second electronic component 22 and the conductive pillars 23. The second encapsulant 25 includes a first surface 25a bonded to the circuit structure 20 and a second surface 25b, 25b′ opposite to the first surface 25a, and end faces 23a of the conductive pillars 23 are exposed from the second surface 25b, 25b′ of the second encapsulant 25.

In an embodiment, the circuit structure 20 includes a plurality of conductive blind vias 202 electrically connected with the first electronic component 21.

In an embodiment, the first electronic component 21 includes an active face 21a electrically connected with the circuit structure 20 and a non-active face 21b opposite to the active face 21a. In an embodiment, in the electronic package 2″ shown in FIGS. 2C″ and 2D″ the non-active face 21b of the first electronic component 21 is exposed from a surface 24a of the first encapsulant 24.

In an embodiment, the second electronic component 22 includes an active face 22a electrically connected with the circuit structure 20 and a non-active face 22b opposite to the active face 22a. In an embodiment, the second electronic component 22 is electrically connected to the circuit structure 20 in the flip-chip manner. In an embodiment, in the electronic package 2′, 2″ shown in FIGS. 2C′, 2D′ or 2C″, 2D″ the non-active face 22b of the second electronic component 22 is exposed from the second surface 25b′ of the second encapsulant 25.

In an embodiment, the conductive pillars 23 are copper pillars.

In an embodiment, the end faces 23a of the conductive pillars 23 are exposed from the second surface 25b, 25b′ of the second encapsulant 25.

In an embodiment, the electronic package 2, 2′, 2″ further includes a plurality of conductive components 27 disposed on the end faces 23a of the conductive pillars 23.

In an embodiment, a conductive adhesive layer (e.g., copper or silver paste) is provided between the conductive pillars 23 and the second electrical contact pads 204 on the second side 20b of the circuit structure 20.

In summary, the electronic package and the method for fabricating the same in accordance with the present disclosure satisfy the need for fine-pitch packaging through the design of the conductive pillars, as well as applications of high voltages and/or high currents. Product yield is also increased.

Furthermore, the first electronic component and the second electronic component are provided on the first side and the second side of the circuit structure, respectively, creating a stacked configuration that significantly reduces the planar area of the electronic package while meeting the needs for multiple functionalities and high performance.

The above embodiments are only used to illustrate the principles of the present disclosure, and should not be construed as to limit the present disclosure in any way. The above embodiments can be modified by those with ordinary skill in the art without departing from the scope of the present disclosure as defined in the following appended claims.

What is claimed is:

1. An electronic package, comprising:
a circuit structure including a first side and a second side opposing the first side;
a first electronic component disposed on the first side of the circuit structure;
a first encapsulant encapsulating the first electronic component;
a second electronic component disposed on the second side of the circuit structure;
a plurality of conductive pillars disposed on the second side of the circuit structure and electrically connected with the circuit structure; and
a second encapsulant encapsulating the second electronic component and the conductive pillars and including a first surface bonded to the circuit structure and a second surface opposing the first surface,
wherein end faces of the conductive pillars are exposed from the second surface of the second encapsulant.

2. The electronic package of claim 1, wherein the circuit structure includes a plurality of conductive blind vias electrically connected with the first electronic component.

3. The electronic package of claim 1, wherein the first electronic component includes an active face electrically connected with the circuit structure and a non-active face opposing the active face.

4. The electronic package of claim 3, wherein the non-active face of the first electronic component is exposed from the first encapsulant.

5. The electronic package of claim 1, wherein the second electronic component includes an active face electrically connected with the circuit structure and a non-active face opposing the active face.

6. The electronic package of claim 5, wherein the second electronic component is electrically connected with the circuit structure in a flip-chip manner.

7. The electronic package of claim 5, wherein the non-active face of the second electronic component is exposed from the second surface of the second encapsulant.

8. The electronic package of claim 1, wherein the conductive pillars are copper pillars.

9. The electronic package of claim 1, further comprising a conductive adhesive layer formed between the conductive pillars and the second side of the circuit structure.

10. The electronic package of claim 1, further comprising a conductive component disposed on the end faces of the conductive pillars.

11. A method for fabricating an electronic package, comprising:
providing a package assembly including a circuit structure having a first side and a second side opposing the first side, a first electronic component disposed on the first side of the circuit structure, and a first encapsulant encapsulating the first electronic component;
providing a second electronic component on the second side of the circuit structure;
disposing a plurality of conductive pillars on the second side of the circuit structure and electrically connecting the conductive pillars with the circuit structure;
forming on the second side of the circuit structure a second encapsulant encapsulating the second electronic component and the conductive pillars, wherein the second encapsulant includes a first surface bonded to the circuit structure and a second surface opposing the first surface; and
removing a portion of the second encapsulant to expose end faces of the conductive pillars from the second surface of the second encapsulant.

12. The method of claim 11, further comprising electrically connecting a plurality of conductive blind vias of the circuit structure with the first electronic component.

13. The method of claim 11, further comprising electrically connecting an active face of the first electronic component with the circuit structure.

14. The method of claim 13, wherein the first electronic component has a non-active face opposing the active face and exposed from the first encapsulant.

15. The method of claim 11, further comprising electrically connecting an active face of the second electronic component with the circuit structure.

16. The method of claim 15, wherein the second electronic component is electrically connected with the circuit structure in a flip-chip manner.

17. The method of claim 15, wherein the non-active face of the second electronic component is exposed from the second surface of the second encapsulant.

18. The method of claim 11, wherein the conductive pillars are copper pillars.

19. The method of claim 11, further comprising forming a conductive adhesive layer between the conductive pillars and the second side of the circuit structure.

20. The method of claim 11, further comprising disposing a conductive component on the end faces of the conductive pillars.
